(19) United States
(12) Patent Application Publication
(10) Pub. No.: US 2016/0291364 A1
(43) Pub. Date: Oct. 6, 2016

(54) LIQUID CRYSTAL DISPLAY AND METHOD OF MANUFACTURING THE SAME

(71) Applicant: Samsung Display Co., Ltd, Yongin-si (JP)

(72) Inventors: Sang Ji PARK, Yongin-si (KR); Ho Yun BYUN, Osan-si (KR); Byung-Gon KUM, Suwon-si (KR); Ji Yeon CHOI, Yongin-si (KR)

(21) Appl. No.: 15/059,117

(22) Filed: Mar. 2, 2016

(30) Foreign Application Priority Data
Apr. 3, 2015 (KR) 10-2015-0047704

(51) Int. Cl. G02F 1/1341; H01L 27/12; G02F 1/1335; G02F 1/1368; G02F 1/1333

(52) U.S. Cl. CPC G02F 1/1341; G02F 1/1368; G02F 1/133377; G02F 1/133512; G02F 1/133528; G02F 1/133514; H01L 27/1259

(57) ABSTRACT

The present disclosure provides a liquid crystal display including: a substrate, a thin film transistor formed on the substrate, a pixel electrode connected to the thin film transistor, a roof layer formed to face the pixel electrode, a liquid crystal layer formed between the pixel electrode and the roof layer and formed of a plurality of microcavities, and a capping layer positioned on the roof layer and formed to cover a trench formed between the plurality of microcavities, in which the capping layer includes a water-soluble polymer material, a photosensitive material, and a moisture-curable adhesive.

### CROSS-REFERENCE TO RELATED APPLICATION

This application claims priority to and the benefit of Korean Patent Application No. 10-2015-0047704 filed in the Korean Intellectual Property Office on Apr. 3, 2015, the entire content of which is incorporated herein by reference.

### BACKGROUND

(a) Field

The present disclosure relates to a liquid crystal display and a method of manufacturing the same.

(b) Description of the Related Art

A liquid crystal display is one of the most common types of flat panel displays currently in use, and includes two display panels formed of field generating electrodes such as a pixel electrode and a common electrode, and a liquid crystal layer interposed therebetween.

The liquid crystal display displays an image by applying a voltage to the field generating electrode to generate an electric field on the liquid crystal layer, and thus to determine alignment of liquid crystal molecules of the liquid crystal layer, and control polarization of incident light.

As one of the liquid crystal displays, a technology of implementing a display by forming a plurality of microcavities in a pixel and filling them with liquid crystal has been developed. In an existing liquid crystal display, two substrates are used, but in this technology, constituent elements may be formed on one substrate to reduce a weight, a thickness, and the like of a device.

In the process of forming the display by filling the liquid crystal in the microcavity, the liquid crystal may be injected through a trench, and after the liquid crystal is injected, an encapsulation process may be performed in order to close the trench and protect the entire element.

However, there are problems in that a material used in the encapsulation process and the liquid crystal comes into contact with each other, causing contamination of the liquid crystal and corrosion of an electrode formed on a substrate and the like due to remaining moisture in the material used in the encapsulation process.

The above information disclosed in this Background section is only for enhancement of understanding of the background of the invention and therefore it may contain information that does not form the prior art that is already known in this country to a person of ordinary skill in the art.

### SUMMARY

The present disclosure has been made in an effort to provide a liquid crystal display where a structure is simplified and corrosion of a lower electrode and the like due to remaining moisture is prevented, and a method of manufacturing the same.

An exemplary embodiment of the present disclosure provides a liquid crystal display including: a substrate, a thin film transistor formed on the substrate, a pixel electrode connected to the thin film transistor, a roof layer formed to face the pixel electrode, a liquid crystal layer formed between the pixel electrode and the roof layer and formed of a plurality of microcavities, and a capping layer positioned on the roof layer and formed to cover a trench that is between the plurality of microcavities, in which the capping layer includes a water-soluble polymer material, a photosensitive material, and a moisture-curable adhesive.

The moisture-curable adhesive may include at least one of a urethane resin, a modified silicon resin, a silicon resin, and a cyanoacrylate resin.

The moisture-curable adhesive may include isocyanate.

The water-soluble polymer material may include at least one of polyvinyl alcohol (PVA), methoxypolyethylene glycol, polyethylene glycol, poly(ethylene glycol) diacrylate, polyethylene glycol dimethacrylate, and polyvinylpyrrolidone.

The photosensitive material may include at least one of ammonium dichromate, a diazo resin, a styrylpyridium group, and a stilbazolium group.

The capping layer may further include a light blocking material, and the light blocking material includes one or more of a water-soluble black dye and a black pigment.

The water-soluble black dye may include at least one of 2-naphthalenesulfonic acid, trisodium 6-[(7-amino-1-hydroxy-3-sulphonato-2-naphthyl)azo]-3-[[4-[[4-amino-6 or 7-sulphonatonaphthyl]azo]phenyl]azo]-4-hydroxynaphthalene-2-sulphonate, trisodium 4-amino-3-[[4-[[4-[(2-amino-4-hydroxyphenyl)azo]phenyl]amino]-3-sulphonatophenyl]azo]-5-hydroxy-6-(phenylazo)naphthalene-2,7-disulphonate, and disodium 4-amino-3,6-bis[[4-[(2,4-diaminophenyl)azo]phenyl]azo]-5-hydroxynaphthalene-2,7-disulphonate 2,7-naphthalenedisulfonic acid.

The capping layer may be continuously formed in the entire trench.

The capping layer may be positioned in the trench, and the capping layers may be discontinuously formed to be spaced apart from each other for each microcavity.

The liquid crystal display may further include a light blocking member positioned in the trench and formed between the capping layer and the substrate.

The liquid crystal display may further include a polarizing plate formed on the capping layer and the roof layer.

The liquid crystal display may further include an overcoat layer covering the capping layer and the roof layer and covered by the polarizing plate.

The roof layer may include a color filter.

Another exemplary embodiment provides a method of manufacturing a liquid crystal display, including: forming a thin film transistor on a substrate, forming a pixel electrode connected to the thin film transistor on the thin film transistor, forming a sacrificial layer on the pixel electrode, forming a roof layer on the sacrificial layer, removing the sacrificial layer to form a microcavity, injecting a liquid crystal material into the microcavity through a trench, applying a capping material to cover the roof layer and the trench, and patterning the capping material to form a capping layer positioned in the trench, in which the capping material includes a water-soluble polymer material, a photosensitive material, and a moisture-curable adhesive.

According to the exemplary embodiment of the present invention, it is possible to simplify a structure of a liquid crystal display by using a capping layer including a material that can perform a photo-process and a component that can adsorb moisture, and to prevent corrosion of a lower electrode and the like by minimizing remaining moisture.

### BRIEF DESCRIPTION OF THE DRAWINGS

FIG. 1 is a top plan view illustrating a liquid crystal display according to an exemplary embodiment of the inventive concept.

FIG. 2 is a cross-sectional view that is taken along line II-II of FIG. 1.

FIG. 3 is a cross-sectional view that is taken along line of FIG. 1.

FIG. 4 is a top plan view illustrating disposal of a capping layer in the liquid crystal display according to the exemplary embodiment of the inventive concept.

FIG. 5 is a top plan view illustrating disposal of the capping layer in the liquid crystal display according to the exemplary embodiment of the inventive concept.

FIG. 6 is a cross-sectional view of the liquid crystal display according to the exemplary embodiment of the inventive concept.

FIG. 7 is a cross-sectional view of the liquid crystal display according to the exemplary embodiment of the inventive concept.

FIG. 8 is a cross-sectional view of the liquid crystal display according to the exemplary embodiment of the inventive concept.

FIGS. 9 and 10 are cross-sectional views illustrating a step of forming the capping layer in a method of manufacturing the liquid crystal display according to the exemplary embodiment of the inventive concept.

### DETAILED DESCRIPTION OF THE EMBODIMENTS

The inventive concept will be described more fully hereinafter with reference to the accompanying drawings, in which exemplary embodiments are shown. As those skilled in the art would realize, the described embodiments may be modified in various different ways, all without departing from the spirit or scope of the inventive concept.

In the drawings, the thickness of layers, films, panels, regions, etc. are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

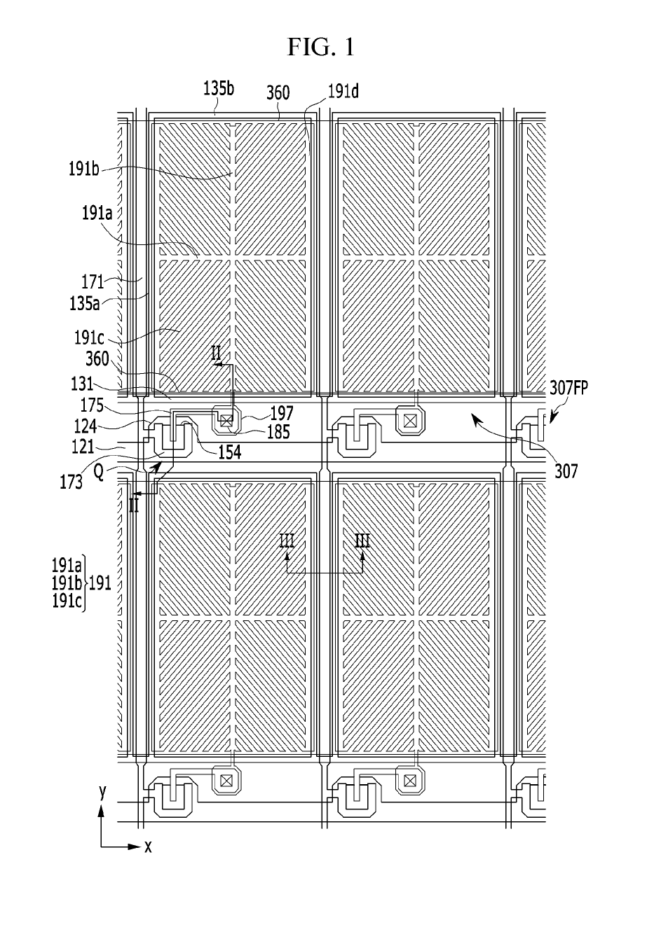

First, a display device according to an exemplary embodiment will be described with reference to FIGS. 1 to 3.

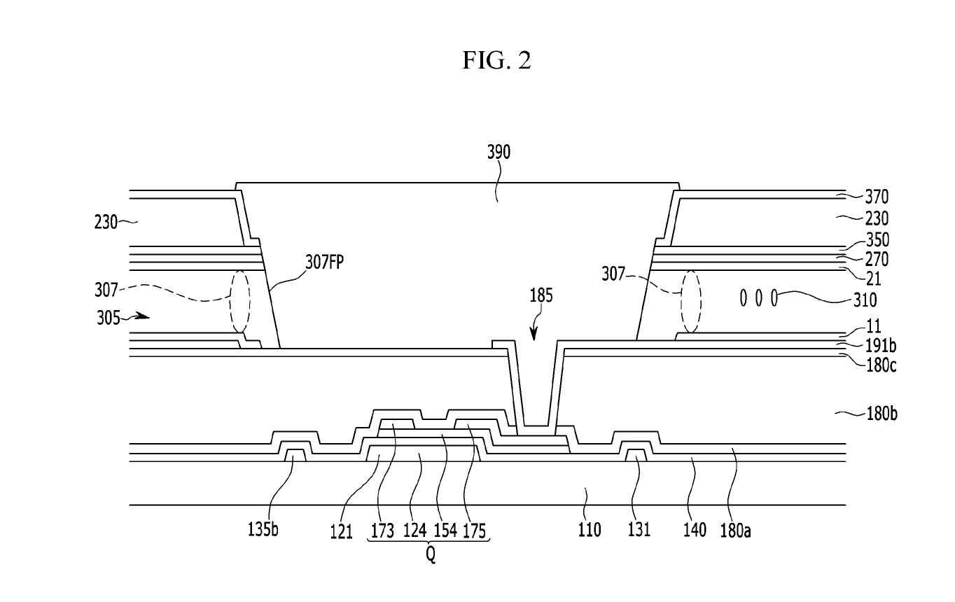

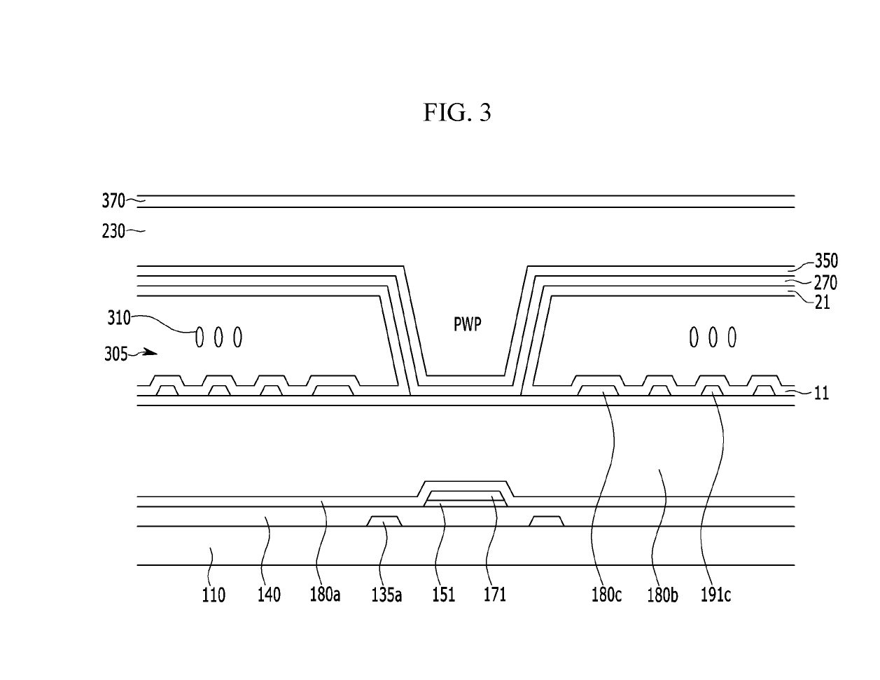

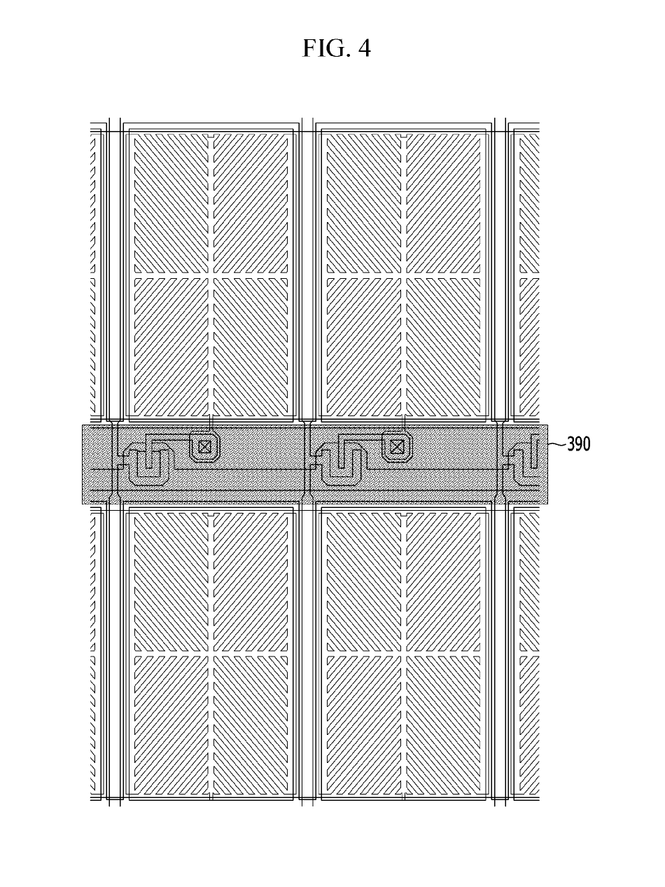

FIG. 1 is a top plan view illustrating a liquid crystal display according to the exemplary embodiment, FIG. 2 is a cross-sectional view that is taken along line II-II of FIG. 1, FIG. 3 is a cross-sectional view that is taken along line III-III of FIG. 1, and FIG. 4 is a top plan view illustrating disposal of a capping layer in the liquid crystal display according to the exemplary embodiment.

FIG. 1 illustrates a 2×2 pixel region portion that is a portion of a plurality of pixel regions, and in the liquid crystal display according to the exemplary embodiment, the pixel regions may be repeatedly arranged vertically and horizontally.

First, referring to FIGS. 1 to 3, a gate line 121 and a storage electrode line 131 are formed on a substrate 110 made of transparent glass, plastic, or the like. The gate line 121 includes a gate electrode 124. The storage electrode line 131 mainly extends in a horizontal direction and transfers a predetermined voltage such as a common voltage Vcom. The storage electrode line 131 includes a pair of vertical portions 135a extending to be substantially vertical to the gate line 121, and a horizontal portion 135b connecting ends of the pair of vertical portions 135a to each other. The vertical portion 135a and the horizontal portion 135b have a structure surrounding a pixel electrode 191.

A gate insulating layer 140 is formed on the gate line 121 and the storage electrode line 131. A semiconductor layer 151 positioned on a lower portion of a data line 171, and a semiconductor layer 154 positioned on lower portions of source and drain electrodes 173 and 175 and a channel portion of a thin film transistor Q are formed on the gate insulating layer 140.

A plurality of ohmic contacts (not illustrated) may be formed on each semiconductor layer 151 and 154, and between the data line 171 and the source/drain electrodes.

Data conductors 171, 173, and 175 including the source electrode 173, the data line 171 connected to the source electrode 173, and the drain electrode 175 are formed on each of the semiconductor layers 151 and 154 and the gate insulating layer 140.

The gate electrode 124, the source electrode 173, and the drain electrode 175 form a thin film transistor Q together with the semiconductor layer 154, and a channel of the thin film transistor Q is formed at the semiconductor layer portion 154 between the source electrode 173 and the drain electrode 175.

A first interlayer insulating layer 180a is formed on an exposed portion of the semiconductor layer 154, which is not covered by the data conductors 171, 173, and 175, the source electrode 173, and the drain electrode 175. The first interlayer insulating layer 180a may include an inorganic material such as silicon nitride (SiNx) and silicon oxide (SiOx).

A second interlayer insulating layer 180b and a third interlayer insulating layer 180c may be positioned on the first interlayer insulating layer 180a. The second interlayer insulating layer 180b may be formed of an organic material, and the third interlayer insulating layer 180c may include an inorganic material such as silicon nitride (SiNx) and silicon oxide (SiOx). The second interlayer insulating layer 180b may be formed of the organic material to reduce or remove a process step. One or two layers of the first interlayer insulating layer 180a, the second interlayer insulating layer 180b, and the third interlayer insulating layer 180c may be omitted.

A contact hole 185 may be formed through the first interlayer insulating layer 180a, the second interlayer insulating layer 180b, and the third interlayer insulating layer 180c. The drain electrode 175 and the pixel electrode 191 positioned on the third interlayer insulating layer 180c may be electrically and physically connected through the contact hole 185. Hereinafter, the pixel electrode 191 will be specifically described.

The pixel electrode 191 may be made of a transparent conductive material such as ITO or IZO.

A whole shape of the pixel electrode 191 is a quadrangle, and the pixel electrode 191 includes a cross-shaped stem portion formed of a horizontal stem portion 191a and a vertical stem portion 191b crossing the horizontal stem portion 191a. Further, the pixel electrode 191 is divided into four sub-regions by the horizontal stem portion 191a and the vertical stem portion 191b, and each sub-region includes a plurality of fine branch portions 191c. Further, in the present exemplary embodiment, an outskirt stem portion 191d connecting the fine branch portions 191c may be further included at left and right outskirts of the pixel electrode 191. In the present exemplary embodiment, the outskirt stem portions 191d are positioned at the left and right outskirts of the pixel electrode 191, but may be positioned to extend to an upper portion or a lower portion of the pixel electrode 191.

The fine branch portion 191c of the pixel electrode 191 forms an angle of about 40° to 45° with the gate line 121 or the horizontal stem portion 191a. Further, the fine branch portions 191c of the two adjacent sub-regions may be orthogonal to each other. Further, a width of the fine branch portion may be gradually increased, and intervals between the fine branch portions 191c may be different from each other.

The pixel electrode 191 includes an extension portion 197 connected at a lower end of the vertical stem portion 191b and having an area that is wider than that of the vertical stem portion 191b, is physically and electrically connected through the contact hole 185 to the drain electrode 175 at the extension portion 197, and receives a data voltage from the drain electrode 175.

The description relating to the thin film transistor Q and the pixel electrode 191 is an example, and a structure of the thin film transistor Q and a design of the pixel electrode 191 may be modified in order to improve lateral surface visibility.

A lower alignment layer 11 is formed on the pixel electrode 191, and the lower alignment layer 11 may be a vertical alignment layer. The lower alignment layer 11 may be formed to include at least one of materials generally used as a liquid crystal alignment layer, such as polyamic acid, polysiloxane, or polyimide. Further, the lower alignment layer 11 may be a photo-alignment layer.

An upper alignment layer 21 is positioned on a portion facing the lower alignment layer 11, and a plurality of microcavities 305 are formed between the lower alignment layer 11 and the upper alignment layer 21. A liquid crystal material including a liquid crystal molecule 310 is injected into the microcavity 305, and the microcavity 305 has an input portion 307. The microcavity 305 may be formed in a column direction of the pixel electrode 191, in other words, a vertical direction. In the present exemplary embodiment, an alignment material forming the alignment layers 11 and 21 and a liquid crystal material including the liquid crystal molecule 310 may be injected into the microcavity 305 by using capillary force. In the present exemplary embodiment, the lower alignment layer 11 and the upper alignment layer 21 are classified according to a position, and as illustrated in FIG. 3, may be connected to each other. The lower alignment layer 11 and the upper alignment layer 21 may be simultaneously formed.

The microcavity 305 is divided in the vertical direction by a plurality of trenches 307FP positioned at a portion overlapping with the gate line 121 to form the plurality of microcavities 305, and the plurality of microcavities 305 may be formed in the column direction of the pixel electrode 191, in other words, the vertical direction. Further, the microcavity 305 is divided in a horizontal direction by a partition wall portion PWP as will be described later to form the plurality of microcavities 305, and the plurality of microcavities 305 may be formed in a row direction of the pixel electrode 191, in other words, in a horizontal direction in which the gate line 121 extends. Each of the microcavities 305 formed in plural may correspond to one or two or more pixel regions, and the pixel region may correspond to a region displaying a screen.

A common electrode 270 and a lower insulating layer 350 are positioned on the upper alignment layer 21. The common electrode 270 receives a common voltage and forms an electric field together with the pixel electrode 191 to which a data voltage is applied to determine an inclination direction of the liquid crystal molecule 310 positioned in the microcavity 305 between the two electrodes. The common electrode 270 and the pixel electrode 191 form a capacitor to maintain the applied voltage even after the thin film transistor Q is turned-off.

The lower insulating layer 350 may be formed of silicon nitride (SiNx) or silicon oxide (SiOx).

Formation of the common electrode 270 in an upper end of the microcavity 305 is described in the present exemplary embodiment, but unlike this, the common electrode 270 can be formed in a lower portion of the microcavity 305 to drive a liquid crystal according to a coplanar electrode mode.

In the present exemplary embodiment, a roof layer 230 is positioned on the lower insulating layer 350, and may be formed of an organic material. The microcavity 305 is formed beneath the roof layer 230, and the roof layer 230 may be hardened by a curing process to maintain a shape of the microcavity 305. That is, the roof layer 230 is formed to be spaced apart from the pixel electrode 191 while the microcavity 305 is interposed between the roof layer and the pixel electrode 191.

The roof layer 230 is formed in an extension direction of the data line 171. In this case, in the trench 307FP, the roof layer 230 is removed to form the input portion 307 corresponding to a portion where an alignment material or a liquid crystal material is injected into the microcavity 305.

The roof layers 230 on the microcavity 305 may meet each other at a portion overlapping with the data line 171 to form the partition wall portion PWP, and the partition wall portion PWP may serve to compartmentalize the microcavities 305. That is, the partition wall portion PWP fills the space between the microcavities 305 adjacent in a horizontal direction. In the embodiment of FIG. 3, the partition wall portion PWP is formed in a structure where the space between the microcavities 305 is completely filled. This is not necessarily a limitation of the inventive concept, and a structure where less than all of the space is filled is contemplated. The partition wall portion PWP may be formed in an extension direction of the data line 171.

In some embodiments, the roof layer 230 may be formed of a color filter. In this case, the color filter may form the partition wall portion PWP, and an interface of the color filters adjacent to each other may be positioned at a portion corresponding to the partition wall portion PWP, and in this case, the adjacent color filters may overlap with each other.

An upper insulating layer 370 is positioned on the roof layer 230. The upper insulating layer 370 may be formed of silicon nitride (SiNx) or silicon oxide (SiOx). As illustrated in FIG. 2, the upper insulating layer 370 may cover a lateral surface portion of the roof layer 230.

Next, referring to FIGS. 2 and 4, a capping layer 390 is positioned in the trench 307FP, and covers the input portion 307 of the microcavity 305 exposed by the trench 307FP. The capping layer 390 may come into contact with the liquid crystal material positioned in the microcavity 305. Specifically, the capping layer 390 is continuously positioned along the trench 307FP. In some embodiments, the capping layer 390 is continuously disposed along the trench 307FP but not disposed on the microcavity 305 in the pixel region.

The capping layer 390 according to the present exemplary embodiment includes a water-soluble polymer material, a photosensitive material, and a moisture-curable adhesive.

In the present exemplary embodiment, the water-soluble polymer material may be polyvinyl alcohol represented by the following Chemical Formula 1. Further, the water-soluble polymer material according to the present exemplary embodiment may include at least one of methoxypolyethylene glycol, polyethylene glycol, poly(ethylene glycol) diacrylate, polyethylene glycol dimethacrylate, and polyvinylpyrrolidone. In Chemical Formula 1, n represents the number of repeating units and may be a natural number.

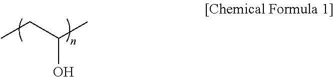

In the present exemplary embodiment, the photosensitive material may include at least one of ammonium dichromate, a diazo resin, a styrylpyridium group, and a stilbazolium group. The capping layer 390 may include the photosensitive material to have a property where a photo-process is feasible.

In the present exemplary embodiment, the capping layer 390 may include the moisture-curable adhesive, and the moisture-curable adhesive means an adhesive initiating polymerization by moisture in the air or moisture attached to a surface of an object to be attached to perform curing.

The moisture-curable adhesive according to the present exemplary embodiment may include isocyanate, but is not limited thereto as long as the adhesive is a moisture-curable adhesive, and for example, the moisture-curable adhesive may be an adhesive including at least one of a urethane resin, a modified silicon resin, a silicon resin, and a cyanoacrylate resin.

The capping layer 390 according to the present exemplary embodiment includes, as described above, the water-soluble polymer material, and thus even though the capping layer 390 is formed, remaining moisture may exist in the capping layer 390. In the case where a separate process is performed in order to remove moisture remaining in the capping layer 390, there is a drawback in views of a separate process time or cost, and moreover, due to remaining moisture, corrosion of the electrode such as the pixel electrode 191 formed in the lower portion of the capping layer 390 may occur.

Therefore, the capping layer 390 according to the present exemplary embodiment may include the moisture-curable adhesive initiating polymerization by moisture to remove remaining moisture without a separate process of removing remaining moisture in a process of forming the capping layer 390 and prevent corrosion of the electrode such as the pixel electrode 191 formed in the lower portion.

Further, the capping layer 390 according to the exemplary embodiment may further include a light blocking material.

In the present exemplary embodiment, the light blocking material may include a water-soluble black dye or a black pigment. The water-soluble black dye may be dissolved in a capping material forming the capping layer 390, and the black pigment may exist in a form where the black pigment is dispersed in the capping material.

The water-soluble black dye according to the present exemplary embodiment may include at least one of 2-naphthalenesulfonic acid, trisodium 6-[(7-amino-1-hydroxy-3-sulphonato-2-naphthyl)azo]-3-[[4-[[4-amino-6 or 7-sulphonatonaphthyl]azo]phenyl]azo]-4-hydroxynaphthalene-2-sulphonate, trisodium 4-amino-3-[[4-[[4-[(2-amino-4-hydroxyphenyl)azo]phenyl]amino]-3-sulphonatophenyl]azo]-5-hydroxy-6-(phenylazo)naphthalene-2,7-disulphonate, and disodium 4-amino-3,6-bis[[4-[(2,4-diaminophenyl)azo]phenyl]azo]-5-hydroxynaphthalene-2,7-disulphonate 2,7-naphthalenedisulfonic acid.

In the case where the capping layer 390 includes the light blocking material, the capping layer 390 may serve as a light blocking member for blocking light leakage. In this case, a separate process for forming the light blocking member may be omitted.

The aforementioned structure of the liquid crystal display according to the present exemplary embodiment is just an example, and numerous variations are feasible. For example, disposal forms of the microcavity 305, the trench 307FP, and the partition wall portion PWP can be changed, the roof layers 230 may be connected to each other in the trench 307FP, and a portion of each roof layer 230 may be formed to be separated from the substrate 110 at the partition wall portion PWP and thus connect the adjacent microcavities 305 to each other.

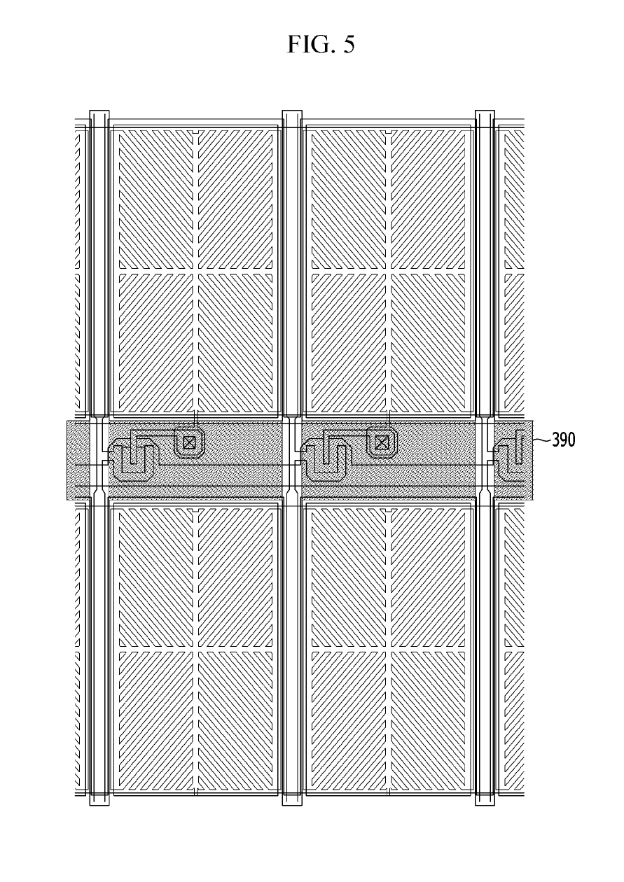

Then, the liquid crystal display according to the exemplary embodiment will be described with reference to FIG. 5.

FIG. 5 is a top plan view illustrating disposal of the capping layer in the liquid crystal display according to the exemplary embodiment.

Since the exemplary embodiment illustrated in FIG. 5 is the same as the exemplary embodiment illustrated in FIGS. 1 to 3 with the exception of a planar position of the capping layer 390, an overlapping description thereof will be omitted.

As illustrated in FIG. 5, the capping layer 390 of the liquid crystal display according to the exemplary embodiment is positioned in the direction in which the gate line 121 extends, in the trench 307FP. However, the capping layers may be spaced apart from each other in an island form for each microcavity 305. That is, in the trench 307FP, which corresponds to the partition wall portion PWP, at a position where the data line 171 is formed, the capping layer 390 may not be formed.

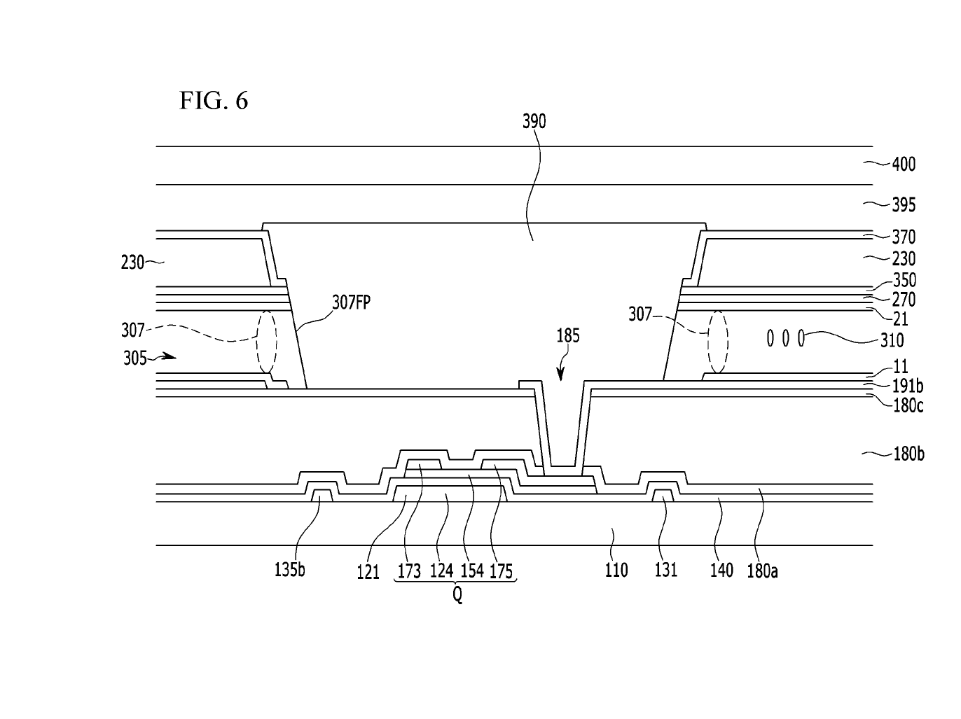

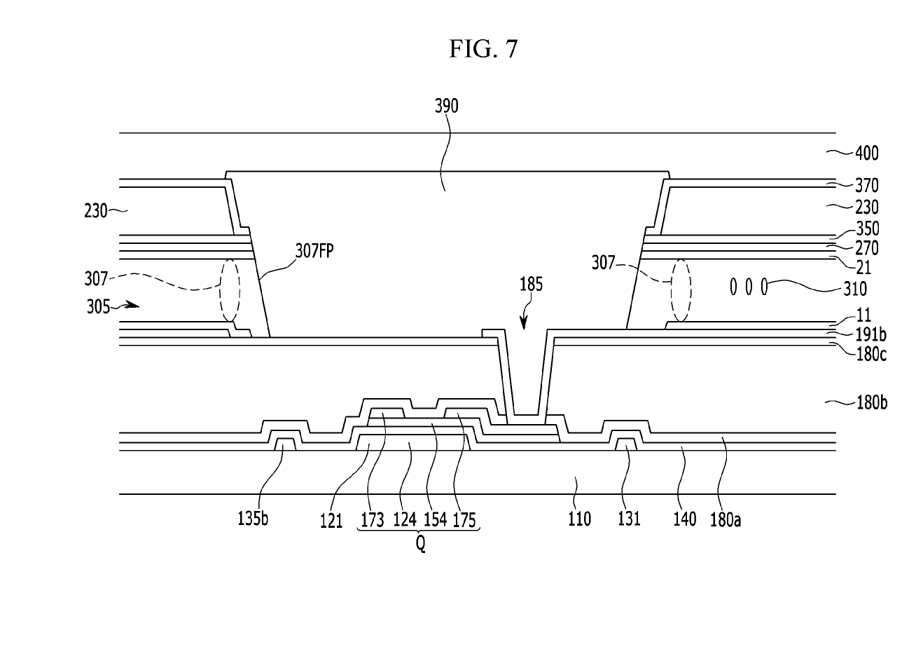

Next, the liquid crystal displays according to the exemplary embodiment will be described with reference to FIGS. 6 and 7.

FIG. 6 is a cross-sectional view of the liquid crystal display according to the exemplary embodiment, and FIG. 7 is a cross-sectional view of the liquid crystal display according to the exemplary embodiment.

Since the exemplary embodiment illustrated in FIGS. 6 and 7 is the same as the exemplary embodiment illustrated in FIGS. 1 to 3, except whether an overcoat layer 395 and a polarizing plate 400 exist or not, an overlapping description thereof will be omitted.

First, as illustrated in FIG. 6, the liquid crystal display according to the exemplary embodiment may further include the overcoat layer 395 formed of an inorganic layer or an organic layer on an entire surface of the substrate 110 including the capping layer 390, and the polarizing plate 400 formed on the overcoat layer 395. The overcoat layer 395 serves to protect the liquid crystal molecule 310 injected into the microcavity 305 from an external impact and planarize the layer. Further, the overcoat layer 395 may serve to block external moisture and oxygen.

Unlike this, as illustrated in FIG. 7, the liquid crystal display may further include only the polarizing plate 400 on the entire surface of the substrate including the capping layer 390 without the overcoat layer 395.

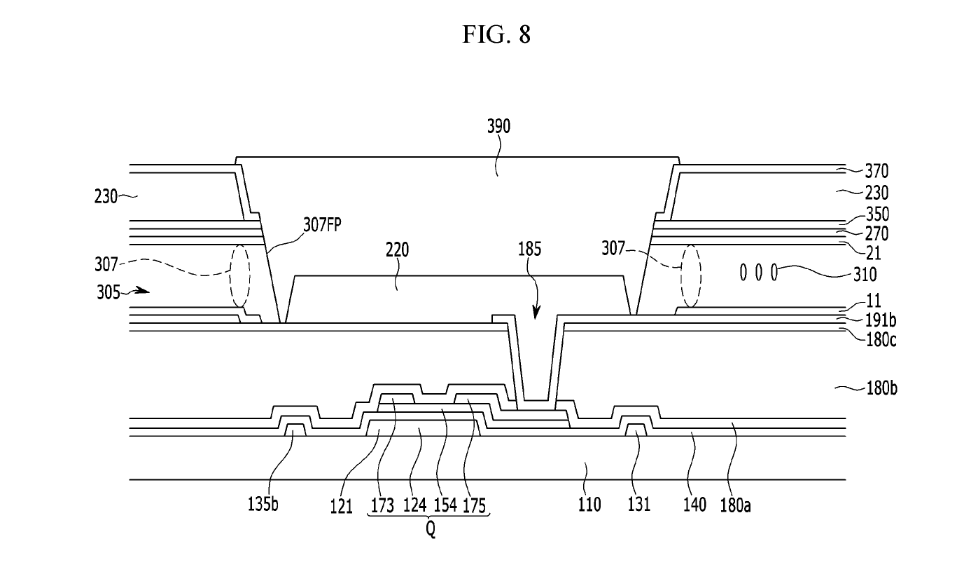

Next, the liquid crystal display according to the exemplary embodiment will be described with reference to FIG. 8.

FIG. 8 is a cross-sectional view of the liquid crystal display according to the exemplary embodiment.

Since the exemplary embodiment illustrated in FIG. 8 is the same as the exemplary embodiment illustrated in FIGS. 1 to 3, except whether a light blocking member 220 exists or not, an overlapping description thereof will be omitted.

As illustrated in FIG. 8, in the liquid crystal display according to the exemplary embodiment, the capping layer 390 does not include the light blocking material, and in the trench 307FP as a region between the adjacent microcavities 305, the light blocking member 220 is formed and may be positioned on the pixel electrode 191 and a third interlayer insulating layer 180c not covered by the pixel electrode. The light blocking member 220 may be formed on a boundary portion of a pixel and the thin film transistor Q to prevent light leakage.

The light blocking member 220 extends upwardly and downwardly along the gate line 121, and may include a horizontal light blocking member 220 covering a region where the thin film transistor Q and the like are positioned and a vertical light blocking member 220 extending along the data line 171. That is, the horizontal light blocking member 220 may be formed in the trench 307FP, and the vertical light blocking member 220 may be formed at a position corresponding to the partition wall portion PWP.

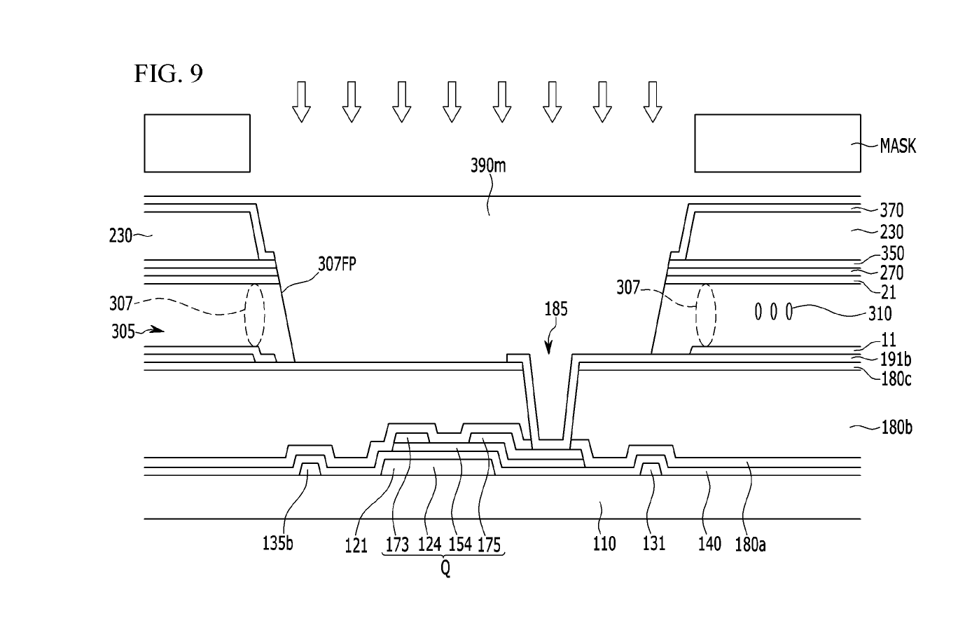

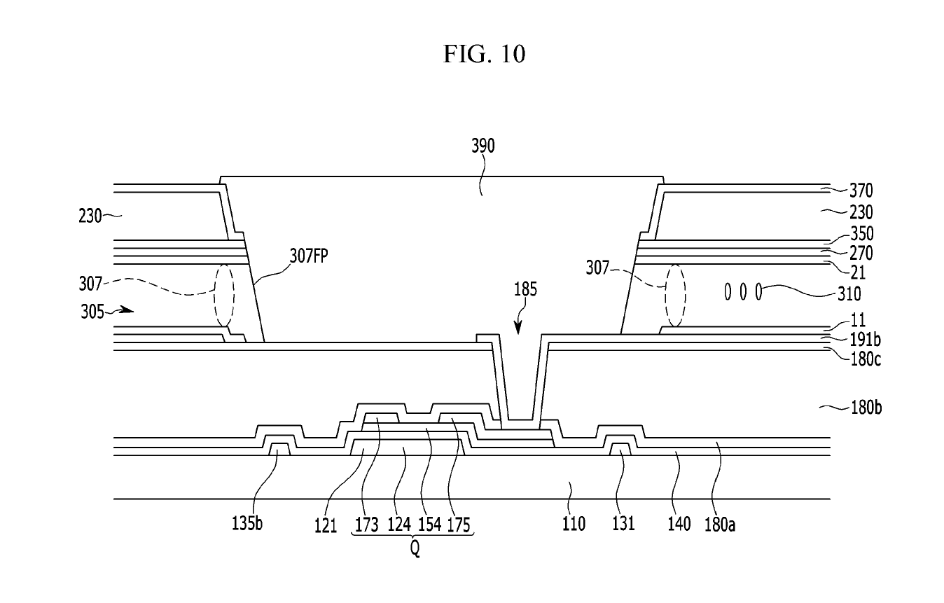

Hereinafter, a method of manufacturing the liquid crystal display according to the exemplary embodiment will be described in brief with reference to FIGS. 9 and 10.

FIGS. 9 and 10 are cross-sectional views illustrating the process of forming the capping layer in a method of manufacturing the liquid crystal display according to the exemplary embodiment.

First, referring to FIG. 9, in the method of manufacturing the liquid crystal display according to the exemplary embodiment, a thin film transistor Q is formed on a substrate 110.

Next, a first interlayer insulating layer 180a, a second interlayer insulating layer 180b, and a third interlayer insulating layer 180c are formed on the thin film transistor Q, and a contact hole 185 is formed therethrough. Thereafter, a pixel electrode 191 is formed on the third interlayer insulating layer 180c, and the pixel electrode 191 is electrically and physically connected to a drain electrode 175 of the thin film transistor Q through the contact hole 185. The pixel electrode 191 may be formed of a transparent conductor such as ITO or IZO.

A sacrificial layer (not illustrated) including an opening portion (not illustrated) is formed in a direction that is parallel to a data line 171 on the pixel electrode 191. In the opening portion, a roof layer 230 may be filled in a subsequent process to form a partition wall portion PWP. The sacrificial layer may be formed of a photoresist material or an organic material excluding the photoresist material.

A common electrode 270 and a lower insulating layer 350 are sequentially formed on the sacrificial layer. The common electrode 270 may be formed of a transparent conductor such as ITO or IZO, and the lower insulating layer 350 may be formed of silicon nitride (SiNx) or silicon oxide (SiO₂). The roof layer 230 and the upper insulating layer 370 are sequentially formed on the lower insulating layer 350. The roof layer 230 may be formed of a color filter. The upper insulating layer 370 may be formed of silicon nitride (SiNx) or silicon oxide (SiO₂). Herein, the roof layer 230 may be removed at a portion where a trench 307FP will be formed by a patterning process or an exposure/developing process.

The upper insulating layer 370, the lower insulating layer 350, and the common electrode 270 positioned to correspond to the trench 307FP are sequentially patterned to expose the sacrificial layer, and the sacrificial layer is removed through the trench 307FP by oxygen (O2) ashing treatment, a wet etching method, or the like. In this case, a microcavity 305 having an input portion 307 is formed. The microcavity 305 is in a hollow space state because the sacrificial layer is removed.

An alignment material is injected through the input portion 307 to form alignment layers 11 and 21 on the pixel electrode 191 and the common electrode 270, and a liquid crystal material including a liquid crystal 310 is injected through the input portion 307 into the microcavity 305 by using an inkjet method and the like.

If the liquid crystal material is injected, since the liquid crystal material may be exposed to the outside by the trench 307FP, a capping material 390m is applied to cover the trench 307FP.

Herein, the used capping material 390m may include a material included in the aforementioned capping layer 390.

Next, as illustrated in FIG. 9, a pixel region corresponding to a plurality of microcavities 305 is covered by a mask to perform exposure. That is, an entire surface of the substrate 110 excluding the trench 307FP may be covered by the mask to perform exposure.

Thereafter, as illustrated in FIG. 10, the mask is removed and the capping material 390m positioned in the pixel region is removed through a developing process to form the capping layer 390 positioned along the trench 307FP.

In the present exemplary embodiment, patterning is performed in a negative photoresist form in which a portion not receiving light is removed during exposure. However, unlike this, the capping material may be formed of a material having a positive photoresist property, and in this case, patterning may be performed by using a mask that is a reverse image of the aforementioned mask.

According to the aforementioned exemplary embodiments, the inventive concept allows a structure to be simplified by using a capping layer including a material that can perform a photo-process and a component that can adsorb moisture and to prevent corrosion of a lower electrode and the like by remaining moisture.

While this inventive concept has been described in connection with what is presently considered to be practical exemplary embodiments, it is to be understood that the inventive concept is not limited to the disclosed embodiments, but, on the contrary, is intended to cover various modifications and equivalent arrangements included within the spirit and scope of the appended claims.

<Description of symbols>

| | |
|---|---|
| 3: Liquid crystal layer | 230: Roof layer |
| 307FP: Trench | 310: Liquid crystal molecule |
| 305: Microcavity | 307: Input portion |
| 350: Lower insulating layer | 370: Upper insulating layer |
| 390: Capping layer | |

What is claimed is:

1. A liquid crystal display comprising:
a substrate,
a thin film transistor formed on the substrate,
a pixel electrode connected to the thin film transistor,
a roof layer formed to face the pixel electrode,
a liquid crystal layer formed between the pixel electrode and the roof layer and formed of a plurality of microcavities, and
a capping layer positioned on the roof layer and formed to cover a trench that is between the plurality of microcavities,
wherein the capping layer includes a water-soluble polymer material, a photosensitive material, and a moisture-curable adhesive.

2. The liquid crystal display of claim 1, wherein:
the moisture-curable adhesive includes at least one of a urethane resin, a modified silicon resin, a silicon resin, and a cyanoacrylate resin.

3. The liquid crystal display of claim 2, wherein:
the moisture-curable adhesive includes isocyanate.

4. The liquid crystal display of claim 2, wherein:
the water-soluble polymer material includes at least one of polyvinyl alcohol (PVA), methoxypolyethylene glycol, polyethylene glycol, poly(ethylene glycol) diacrylate, polyethylene glycol dimethacrylate, and polyvinylpyrrolidone.

5. The liquid crystal display of claim 2, wherein:
the photosensitive material includes at least one of ammonium dichromate, a diazo resin, a styrylpyridium group, and a stilbazolium group.

6. The liquid crystal display of claim 2, wherein:
the capping layer further includes a light blocking material, and
the light blocking material includes one or more of a water-soluble black dye and a black pigment.

7. The liquid crystal display of claim 6, wherein:
the water-soluble black dye includes at least one of 2-naphthalenesulfonic acid, trisodium 6-[(7-amino-1-hydroxy-3-sulphonato-2-naphthyl)azo]-3-[[4-[[4-amino-6 or 7-sulphonatonaphthyl]azo]phenyl]azo]-4-hydroxynaphthalene-2-sulphonate, trisodium, 4-amino-3-[[4-[[4-[(2-amino-4-hydroxyphenyl)azo]phenyl]amino]-3-sulphonatophenyl]azo]-5-hydroxy-6-(phenylazo)naphthalene-2,7-disulphonate, and disodium 4-amino-3,6-bis[[4-[(2,4-diaminophenyl)azo]phenyl]azo]-5-hydroxynaphthalene-2,7-disulphonate 2,7-naphthalenedisulfonic acid.

8. The liquid crystal display of claim 6, wherein:
the capping layer is continuously formed in the entire trench.

9. The liquid crystal display of claim 6, wherein:
the capping layer is positioned in the trench, and
the capping layers are discontinuously formed to be spaced apart from each other for each microcavity.

10. The liquid crystal display of claim 1, further comprising:
a light blocking member positioned in the trench and formed between the capping layer and the substrate.

11. The liquid crystal display of claim 1, further comprising:
a polarizing plate formed on the capping layer and the roof layer.

12. The liquid crystal display of claim 11, further comprising:
an overcoat layer covering the capping layer and the roof layer and covered by the polarizing plate.

13. The liquid crystal display of claim 1, wherein:
the roof layer includes a color filter.

14. A method of manufacturing a liquid crystal display, comprising:
forming a thin film transistor on a substrate,
forming a pixel electrode connected to the thin film transistor on the thin film transistor,
forming a sacrificial layer on the pixel electrode,
forming a roof layer on the sacrificial layer,
removing the sacrificial layer to form a microcavity,
injecting a liquid crystal material into the microcavity through a trench,
applying a capping material to cover the roof layer and the trench, and
patterning the capping material to form a capping layer positioned in the trench,
wherein the capping material includes a water-soluble polymer material, a photosensitive material, and a moisture-curable adhesive.

15. The method of claim 14, wherein:
the moisture-curable adhesive includes at least one of a urethane resin, a modified silicon resin, a silicon resin, and a cyanoacrylate resin.

16. The method of claim 15, wherein:
the moisture-curable adhesive includes isocyanate.

17. The method of claim 15, wherein:
the water-soluble polymer material includes at least one of polyvinyl alcohol (PVA), methoxypolyethylene glycol, polyethylene glycol, poly(ethylene glycol) diacrylate, polyethylene glycol dimethacrylate, and polyvinylpyrrolidone.

18. The method of claim 15, wherein:
the photosensitive material includes at least one of ammonium dichromate, a diazo resin, a styrylpyridium group, and a stilbazolium group.

19. The method of claim 15, wherein:
the capping layer further includes a light blocking material, and
the light blocking material includes one or more of a water-soluble black dye and a black pigment.
